(19) United States
(12) Patent Application Publication
(10) Pub. No.: US 2008/0041442 A1
(43) Pub. Date: Feb. 21, 2008

(54) Frameless Photovoltaic Module

(76) Inventor: Jack Isaac Hanoka, Brookline, MA (US)

Correspondence Address: PROSKAUER ROSE LLP, ONE INTERNATIONAL PLACE, BOSTON, MA, 02110, US

(21) Appl. No.: 11/766,511

(22) Filed: Jun. 21, 2007

Related U.S. Application Data
(60) Provisional application No. 60/815,482, filed on Jun. 21, 2006.

(51) Int. Cl. H01L 31/048; B29C 35/08

(52) U.S. Cl. 136/251; 264/477

(57) ABSTRACT

A photovoltaic module includes a backsheet layer, a transparent upper support layer, a photovoltaic layer positioned between the backsheet layer and the transparent upper support layer, and a non-conductive frame. The photovoltaic layer includes a plurality of electrically connected photovoltaic cells, and the non-conductive frame includes at least one irradiated polymer element adapted to contact a portion of backsheet layer and the transparent upper support layer. The backsheet layer, the transparent upper support layer, the photovoltaic layer, and the non-conductive frame are laminated to form the photovoltaic module.

### CROSS-REFERENCE TO RELATED APPLICATIONS

This application claims the benefits of and priority to U.S. provisional patent application Ser. No. 60/815,482 filed on Jun. 21, 2006, the entire disclosure of which is herein incorporated by reference.

### FIELD OF THE INVENTION

The invention generally relates to a photovoltaic module. In particular, the invention relates to a photovoltaic module that includes a non-conductive edge element, which can be light weight, easy to install, and can allow for improved sealing of the photovoltaic module.

### BACKGROUND OF THE INVENTION

Photovoltaic modules, particularly those made with crystalline silicon solar cells, can be formed by providing a sheet of tempered glass, depositing a transparent encapsulant on the glass, positioning solar cells on the encapsulant, depositing a second encapsulant layer on the cells, positioning a backsheet layer on top of the second encapsulant layer, securing a perimeter aluminum frame, and bonding a junction box to the backsheet on the rear of the modules. Common practice is to have wires with plugs emerging from this junction box. Furthermore, bypass diodes can be incorporated in the junction box to provide for protection against localized hot spots in the module. Prior to the installation of the aluminum frame, a strip of some type of gasketing material is applied to the edge of the glass as a cushioning layer to protect the edge of the tempered glass from shattering due to an edge impact. Disadvantages of an aluminum frame include: the material and labor cost associated with it; the increase in the thickness and the weight of the module; the requirement to ground such a module in an installation; and reduced stiffness of the module as photovoltaic modules become larger. There is a limit to how much stiffness an aluminum perimeter frame can provide cost-effectively.

There is a tendency in the industry towards larger modules. As the modules become larger, there is a concomitant requirement to use a heavier aluminum frame and thicker glass. These requirements are due to the wind, snow and ice loading requirements to satisfy the universally accepted qualification criteria that insure that the deformation of the module under load is limited to where the glass does not break or that it is not dislodged from the aluminum frame. An additional problem with excessive module deflection under load is the possibility of introducing cracks in cells, which can affect thin silicon solar cells.

### SUMMARY OF THE INVENTION

The invention, in one embodiment, features a frameless, light weight photovoltaic module with improved stiffness for better resistance against deflection due to wind, ice, snow loads, or other environmentally created conditions. The photovoltaic module can be formed with a protective edge element around the superstrate glass of the module. The edge element can be low cost and simple to form, can allow for a variety of mounting possibilities, can provide greater stiffness to a module than that of an aluminum frame, and/or can obviate the need for grounding a module.

The photovoltaic module can include a stiffening and/or mounting element applied to the rear of the module so that the need for an aluminum frame and for thicker glass can be mitigated or eliminated. The stiffening and/or mounting element can be placed on the rear of the module so that greater resistance to deflection under load is provided. The likelihood of cracking cells due to such deflection can be reduced—an important advantage as the industry shifts to thin solar cells. Furthermore, the need for attaching grounding wires to the module when an installation is being done can be minimized or eliminated. Without exposed metal on the module, the need for grounding can be obviated entirely. Cost savings for module installers, who normally need to run a grounding wire connected to each module in an installation, can be realized.

Aesthetically acceptable photovoltaic modules can be formed using a mold. For example, the photovoltaic module can be formed within the mold, and the mold, along with the module assembly, can be placed in a laminator. However, such a procedure can be costly and, therefore, lack commercial viability. An embodiment of the photovoltaic module described herein can eliminate the need for a mold by providing an edge element that includes sufficiently cross-linked polymers.

In one aspect, the invention features a method of forming a photovoltaic module. The method includes extruding a polymer material to form at least one edge element. The at least one edge element is irradiated to cross-link the polymer material. The at least one edge element is bonded to a photovoltaic component, which includes a plurality of interconnected photovoltaic cells disposed between a transparent layer and a backsheet layer. The at least one edge element is bonded to a front surface of the transparent layer and a back surface of the backsheet layer. The at least one edge element and the photovoltaic component are laminated in the absence of a mold, to form the photovoltaic module.

In another aspect, the invention features a method of forming a laminated photovoltaic module. The method includes providing a photovoltaic component with a plurality of electrically connected photovoltaic cells disposed between a backsheet layer and a transparent layer. At least one edge member including an irradiated polymer is attached to the photovoltaic component so as to contact a front surface of the transparent layer and a back surface of the backsheet layer. At least one corner member including an irradiated polymer is attached to the photovoltaic component so as to contact the front surface of the transparent layer and the back surface of the backsheet layer, and to form together with the at least one edge element at least a portion of a non-conductive frame about the photovoltaic component. The photovoltaic component together with the at least one edge member and the at least one corner member is laminated to form the laminated photovoltaic module.

In yet another aspect, the invention features a system for protecting edges of a photovoltaic module. The system includes a plurality of edge members including a first irradiated polymer. The plurality of edge members is adapted to physically contact both an upper surface and a lower surface of the photovoltaic module. Each edge member seals a respective edge of the photovoltaic module. The system further includes a plurality of corner members including a second irradiated polymer. The plurality of corner members is adapted to physically contact both the upper surface and the lower surface of the photovoltaic module. Each corner member seals a respective corner of the photovoltaic module.

In another aspect, the invention features a photovoltaic module including a lower support layer, an upper support layer, a photovoltaic layer, and a non-conductive frame. The upper support layer includes a transparent sheet. The photovoltaic layer is positioned between the lower support layer and the upper support layer. The photovoltaic layer includes a plurality of electrically connected photovoltaic cells. The non-conductive frame includes at least one irradiated polymer element adapted to contact a portion of the lower support layer and the upper support layer. The lower support layer, the upper support layer, the photovoltaic layer, and the non-conductive frame are laminated to form the photovoltaic module.

In various examples, any of the aspects above or any of the methods or systems or modules described herein, can include one or more of the following features. In some embodiments, the edge element can be a single member disposable around the perimeter of the photovoltaic component. In certain embodiments, the edge element can include edge members and corner members. In various embodiments, the corner members can overlap the edge members.

In some embodiments, a bonding agent can be disposed on a surface of the at least one edge element prior to bonding. In certain embodiments, the at least one edge element can be irradiated with an energy of about 2 megarad (MR) to about 20 MR. In various embodiments, the at least one edge element includes a non-electrically conductive material.

In some embodiments, the edge element can be irradiated to sufficiently cross-link the polymer material so that the polymer material does not flow during the lamination step. In certain embodiments, the bonding agent can be irradiated.

In some embodiments, the edge element includes a plurality of edge members. In certain embodiments, at least four edge members can be attached to the photovoltaic component. In certain embodiments, four corner elements can be attached to the photovoltaic component and the at least four edge elements. In various embodiments, each corner element can overlap two edge elements.

In some embodiments, a bonding layer can be disposed on a surface of each edge element, each edge member, and/or each corner member prior to attaching the piece to the photovoltaic component.

In certain embodiments, the bonding layer can include an acid co-polymer of methacrylic acid. In various embodiments, the bonding layer can include an acid co-polymer of acrylic acid and polyethylene. In some embodiments, the bonding layer can include an ionomer.

In certain embodiments, the bonding layer can be disposed on each corner element. The bonding layer and each corner element can be irradiated with an energy of about 2 MR to about 20 MR prior to attaching the corner elements to the photovoltaic component. In various embodiments, a silane coupling agent can be applied to at least a portion of the transparent layer prior to attaching the at least one edge member to the photovoltaic component.

In some embodiments, at least one non-electrically conductive mounting element can be attached to the laminated photovoltaic module. In certain embodiments, the non-electrically conductive mounting element can include a filled polymer. In various embodiments, the filled polymer can include a filler such as aluminum trihydrate, calcium carbonate, calcium sulfate, carbon fibers, glass fibers, hollow glass microspheres, kaolin clay, mica, crushed silica, synthetic silica, talc, wollastonite, nano-clay particles, and sawdust.

In some embodiments, the first irradiated polymer and the second irradiated polymer can be formed from the same initial polymer material. In certain embodiments, the first irradiated polymer and/or the second irradiated polymer can be irradiated at a dosage to create both thermoset and thermoplastic properties. In various embodiments, the first irradiated polymer and/or the second irradiated polymer can be irradiated at a dosage of about 2 MR to about 20 MR.

In some embodiments, each edge element or each edge member can be tapered. In certain embodiments, each edge member can have a U-shape. In various embodiments, each corner member can have a hollow L-shape.

In some embodiments, the bonding layer can be irradiated with an electron beam. In certain embodiments, a bonding layer can be disposed on at least a portion of an interior surface of each edge element so as to contact at least one of the upper surface and the lower surface of the photovoltaic module. In various embodiments, a bonding layer can be disposed on at least a portion of an interior surface of each corner element so as to contact at least a portion of the respective corner of the photovoltaic module.

In some embodiments, each of the irradiated polymer elements can overlap at least one other irradiated polymer element to form the non-conductive frame. In certain embodiments, the irradiated polymer elements can include at least one edge member and at least one corner member. In various embodiments, the irradiated polymer elements can have both thermoset and thermoplastic properties.

In some embodiments, at least one non-electrically conductive mounting element can be disposed on a lower support layer side of the photovoltaic module. The at least one non-electrically conductive mounting element can provide an increase in stiffness to the photovoltaic module. In certain embodiments, the at least one non-electrically conductive mounting element can be made of a composite material including a polymer and a filler.

Other aspects and advantages of the invention will become apparent from the following drawings, detailed description, and claims, all of which illustrate the principles of the invention, by way of example only.

### BRIEF DESCRIPTION OF DRAWINGS

The advantages of the invention described above, together with further advantages, may be better understood by referring to the following description taken in conjunction with the accompanying drawings. The drawings are not necessarily to scale, emphasis instead generally being placed upon illustrating the principles of the invention.

FIG. 1 shows a sectional view of an exemplary photovoltaic module.

FIG. 2 shows a sectional view of another exemplary photovoltaic module.

FIG. 3 shows a plan view of a photovoltaic module with an edge element.

FIG. 4 shows a plan view of a photovoltaic module with edge members and corner members.

FIG. 5 shows a perspective view of an edge element.

FIG. 6 shows a perspective view of a corner member.

FIG. 7 shows a plan view of a photovoltaic module with an element for stiffening and/or mounting disposed on a back surface.

### DETAILED DESCRIPTION OF THE INVENTION

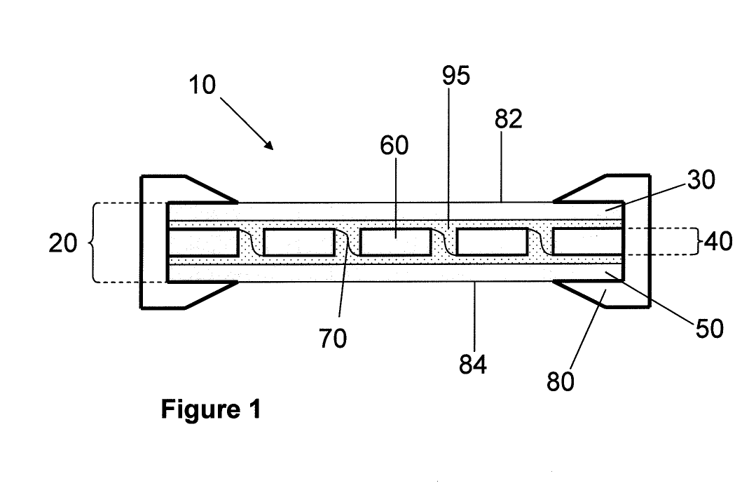

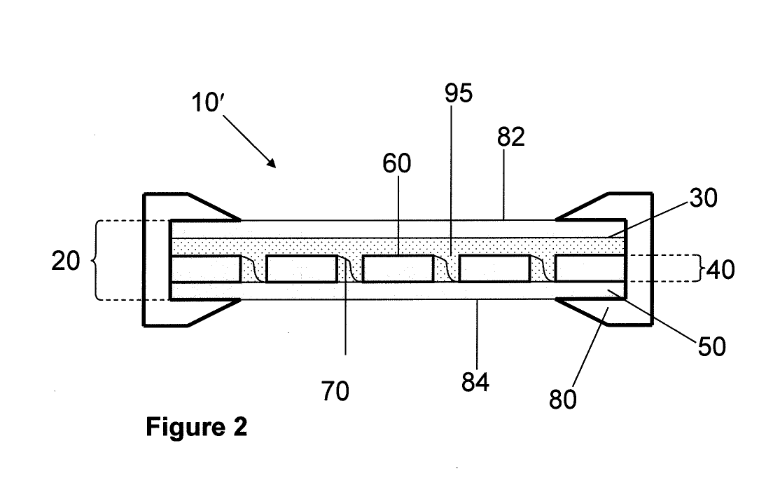

FIG. 1 shows a cross-section of an exemplary photovoltaic module 10. The photovoltaic module 10 includes a photovoltaic component 20, which includes a transparent layer 30, a photovoltaic layer 40, and a backsheet layer 50. The photovoltaic layer 40 includes a plurality of photovoltaic cells 60 that are interconnected using leads 70. An edge element 80 is disposed around the edges of the photovoltaic component 20. The edge element 80 can be bonded to a front surface 82 of the transparent layer 30 and a back surface 84 of the backsheet layer 50. The photovoltaic layer 40 is encapsulated in encapsulation layer 95. FIG. 2 shows an embodiment of a photovoltaic module 10′ where the photovoltaic cells 60 are disposed on an inner surface of the backsheet layer 50. Photovoltaic module 10 can be formed by laminating the transparent layer 30, the photovoltaic layer 40, the backsheet layer 50, the edge element 80, and the encapsulation layer 95 in the absence of a mold.

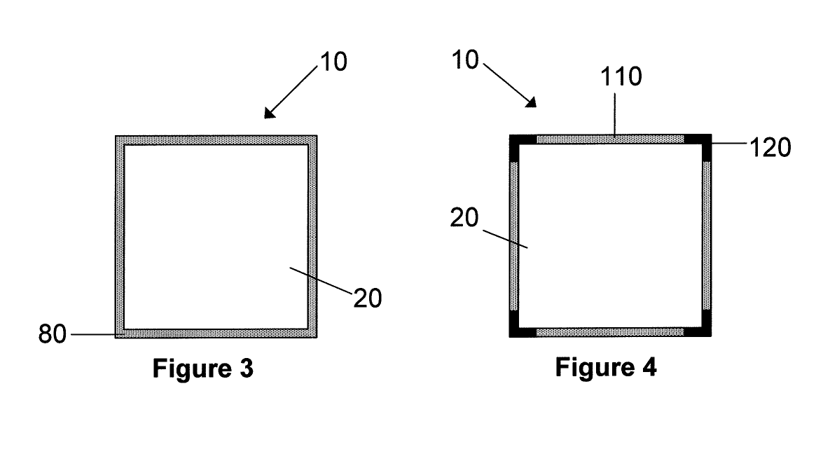

FIG. 3 shows an exemplary photovoltaic module 10 with an edge element 80. In this embodiment, the edge element 80 is a single member disposed around the perimeter edge of the photovoltaic module 10. FIG. 4 shows an exemplary photovoltaic module 10 with an edge element 80 formed from edge members 110 and corner members 120. The edge members 110 can be bonded to the edges of the photovoltaic component 20, and the corner members 120 can be bonded to the corners of the photovoltaic component 20. A portion of each corner member 120 can overlap a portion of each adjacent edge member 110.

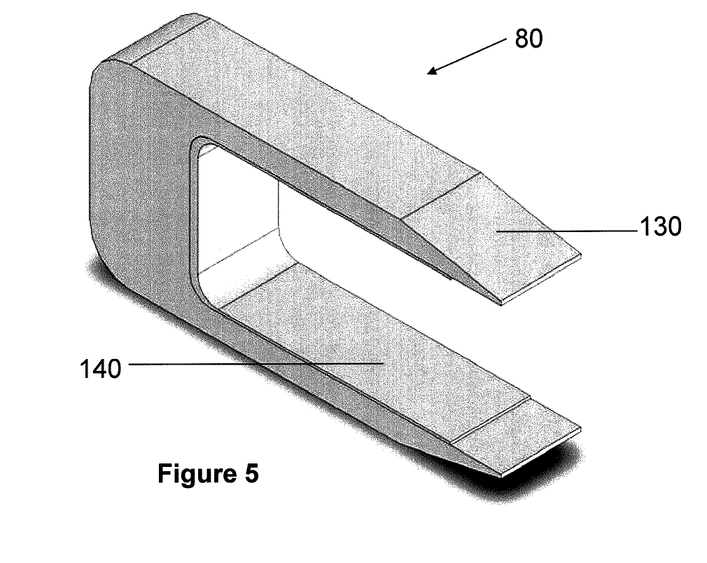

FIG. 5 shows an exemplary embodiment of an edge element 80. The edge element 80 can be formed by a profile extrusion technique. For example, the edge element 80 can be formed by extruding a polymer material. The extruded polymer material can be irradiated prior to being bound to the photovoltaic component 20. The edge element 80 can have a U-shape, and can have a tapered end 130. The taper 130 can provide better sealant properties because there is little opportunity for water to gather along the edge of a module, which can be a recurrent issue with aluminum frames.

The edge element 80 can have a bonding layer 140 on the inside surface. The bonding layer 140 can allow for very strong bonds to surfaces of the transparent layer 30 and/or the backsheet layer 50. The bonding layer 140 can be an acid co-polymer of methacrylic acid or acrylic acid and polyethlylene. The bonding layer 140 can also be an ionomer.

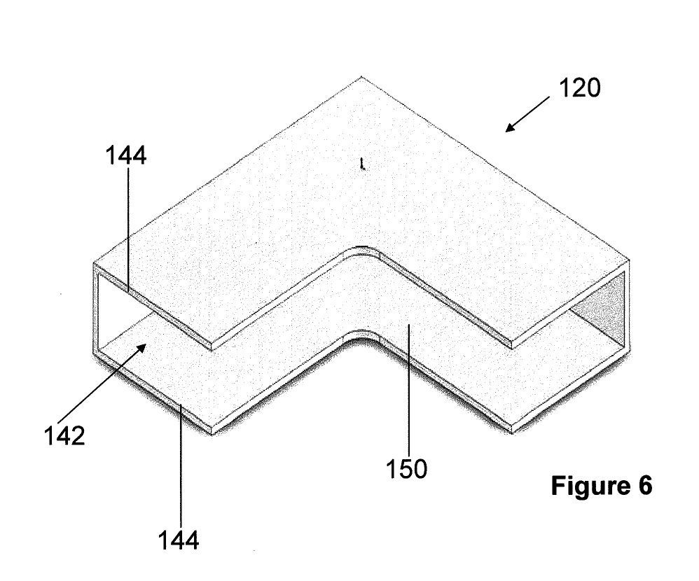

FIG. 6 shows a corner member 120. The corner member 120 can have an L-shape, and include a channel 142 between opposing sides 144. A bonding layer 140 can be applied to inner surfaces of the opposing sides 144. In some embodiments, the corner members 120 can be formed from a polymer material by an injection molding technique. The corner members 120 can overlap adjacent edge members during bonding to the photovoltaic component. The corner members 120 can be irradiated prior to being bound to the photovoltaic component.

The material of the edge element 80, the edge member 110, or the corner member 120 can be of similar composition to the material of the backsheet layer 50. For example, a polymer material can be used. The polymer material can possess thermal creep resistance while retaining enough thermoplasticity to be bonded to itself or other materials. The polymer material can be irradiated with a high energy electron beam radiation. This irradiation procedure can produce cross-linking in the polymer material. However, there is still some residue of thermoelasticity. This means that the material can be sufficiently thermoplastic to be heat bonded to other surfaces and materials. The irradiated polymer material shows a dramatic increase in its thermal creep resistance. The polymer material can be irradiated to a point where it still retains some thermoplastic properties. As used herein, the term “thermoset” refers to a polymer's quality of solidifying when either heated or reacted chemically without being able to be re-melted or be remolded. Also, as used herein, the term “thermoplastic” refers to a material's quality of repeatedly softening when heated and hardening when cooled. A thermoplastic polymer material is capable of bonding to an adjacent surface and being molded during a lamination procedure.

In certain embodiments, the polymer material can be a thermoplastic olefin, which can be composed of two different kinds of ionomers, mineral fillers, and/or pigments. Ionomer is a generic name which herein refers to either a co-polymer of ethylene and methacrylic acid or acrylic acid, which has been neutralized with the addition of a salt which supplies a cation such as Na⁺, Li⁺, Zn⁺⁺, Al⁺⁺⁺, Mg⁺⁺, etc. The material can have covalent bonds which polymers typically have, but can also have regions of ionic bonding. The latter can impart a built-in cross linking into the material. Ionomers are typically tough and weatherable polymers. The combination of two ionomers can produce a synergistic effect, which improves the water vapor barrier properties of the material over and above the barrier properties of either of the individual ionomer components.

The addition of a mineral filler, such as glass fiber, to the backsheet layer material can provide for a lower coefficient of thermal expansion. This can preserve strong, long lasting bonds to all the adjacent surfaces in a module which undergoes ambient temperature extremes. The glass fibers can also improve the water vapor and oxygen barrier properties of the material and increase the flexural modulus three or four times over the ionomers themselves. This can make the backsheet layer strong, but also flexible. A pigment, such as carbon black, can be added to the backsheet layer material to provide weathering properties such as resistance to degradation from exposure to ultraviolet light. To improve reflectivity, the backsheet or an edge element can be made white with the addition of TiO₂. In some embodiments, the polymer material can be a flexible sheet of thermoplastic polyolefin, which can include a sodium ionomer, a zinc ionomer, about 10-20% glass fibers, about 5% carbon black, or about 7% TiO₂. In some embodiments, the material can be an ionomer or an acid co-polymer with about 25% high density polyethylene, along with a mineral filler.

One or more of the backsheet layer 50, the edge element 80, the encapsulant material 95, and the bonding layer 140 can be electron beam irradiated following profile extrusion. The irradiation can cross-link both the edge element 80 and the bonding layer 140. As a result, the electron beam irradiation produces a material that can have both thermoset and thermoplastic properties.

The edge element 80 does not need to be set in a mold to prevent flow of the polymer during assembly of the photovoltaic module 10. In general, polymers that are not sufficiently cross-linked or not contained in a mold during the lamination process flow readily under the temperature and pressure conditions of lamination, thereby creating a non-esthetically acceptable photovoltaic module.

In some embodiments, the radiation dosage used can be in the range of about 1 MR to about 30 MR. In various embodiments, the radiation dosage used can be in the range of about 2 MR to about 20 MR. In certain embodiments, the radiation dosage can be in the range of about 2 MR to about 12 MR. In various embodiments, the radiation dosage can be in the range of 12-16 MR.

In various embodiments, the encapsulant layer 95 can be an irradiated transparent layer. In some embodiments, the encapsulant layer 95 can be copolymers of ethylene. In certain embodiments, ethylene vinyl acetate (EVA), a copolymer of vinyl acetate and ethylene, can be used. In various embodiments, the irradiated transparent encapsulant layer 95 can be an ionomer. The ionomer layers can be derived from any direct or grafted ethylene copolymer of an alpha olefin having the formula R—CH═CH₂, where R is a radical selected from the class consisting of hydrogen and alkyl radicals having from 1 to 8 carbon atoms and alpha, beta-ethylenically unsaturated carboxylic acid having from 3 to 8 carbon atoms. The acid moieties can be randomly or non-randomly distributed in the polymer chain. The alpha olefin content of the copolymer can range from 50-92%. The unsaturated carboxylic acid content of the copolymer can range from about 2 to 25 mole percent, based on the alpha olefin-acid copolymer, and the acid copolymers having from 10 to 90 percent of the carboxylic acid groups ionized by neutralization with metal ions from any of the group I, II or III type metals.

In some embodiments, the encapsulant layer 95 can be a layer of metallocene polyethylene disposed between two layers of ionomer. The layer of metallocene polyethylene can include a copolymer (or comonomer) of ethylene and hexene, octene, and butene, and the first and second layers of ionomer can have at least 5% free acid content. The layers of metallocene polyethylene and ionomer can be substantially transparent. In certain embodiments, the metallocene polyethylene can be ethylene alpha-olefin including co-monomer of octene, and the ionomer can be a sodium ionomer comprising methacrylic acid. An encapsulant material which is a combination of two materials can allow for the exploitation of the best properties of each material while overcoming the limitations of each material if used alone. The outer ionomer layers can allow the encapsulant material to bond strongly to the adjacent surfaces. The inner metallocene polyethylene layer can be a highly transparent, low cost thermoplastic material. The two ionomer layers can be thin (e.g., about 0.001″ thick), and can have a high acid content (e.g., at least 5% free acid). The high acid content can provide for strong adhesion and cohesive bond failure and increased light transmission. The metallocene polyethylene, which can have some co-monomer of octene, can have optical clarity and improved physical properties.

In various embodiments, the transparent layer 30 can be glass. In some embodiments, a silane coupling agent can be applied as a very thin layer to the glass prior to the application of the edge element 80 onto the glass. The criterion of hydrolytic stability can be used to experimentally measure the strength of the bond between the edge element 80 and glass.

In some embodiments, an acid-copolymer can be used as the bonding agent. The acid-copolymer can be co-extruded during the profile extrusion of the edge element 80. A thin layer of a silane coupling agent can be applied to the glass edges. A measure of the bond strength is hydrolytic stability. A 1″ wide strip of material bonded to a glass slide is subjected to hot water for a certain period of time. Following this, a right angle pull test is used to determine the so-called peel strength—a measure of the bond strength. For a sealant material such as ethyl vinyl acetate (EVA), the peel strength for 4 days in boiling water is 5.2 to 11.3 lbs/inch. An edge element without an acid co-polymer after 115 hours in boiling water showed a peel strength of 0-1 lbs/inch. An edge element with a 2 mm layer of acid co-polymer after 180 hours in boiling water showed the peel strength of 20-24 lbs/inch. A rule of thumb is that: a bond strong after 1 week at 70° C., can last 75 years. A bond strong after 1 week of boiling water, can last forever.

A photovoltaic component 20 can be formed by interconnecting a plurality of photovoltaic cells 60. A transparent layer 30, such as a tempered glass sheet, can be placed on a lay-up table. A first encapsulant layer can be disposed on the transparent layer 30. The plurality of photovoltaic cells 60 can be placed over the encapsulant layer. A second encapsulant layer can be placed over the plurality of photovoltaic cells 60. A backsheet layer 50 can be placed over the second encapsulant layer. In certain embodiments, the backsheet layer 50 can be placed on the plurality of photovoltaic cells 60 without an intervening second encapsulating layer. One or more edge elements can be disposed on the edges and/or corners of the assembly. The entire assembly can be placed in a laminator and laminated to form a photovoltaic module 10. After lamination, the excess encapsulant layer materials can be trimmed off. A junction box and stiffening elements 100 can be installed on the photovoltaic module 10. The heat and pressure of the lamination process can produce a sealed module.

Since the edge element 80, the edge members 110, and/or the corner members 120 can be formed of a polymer or non-metallic material, they can be positioned in direct physical contact to the photovoltaic module 10, whereas in a frame made of electrically conductive material such as aluminum, the edge element 80, need to be insulated from the photovoltaic module.

During lamination, the edge element 80 can seal the edges of the photovoltaic module 10 after reaching a sufficiently high pressure and temperature. Such a temperature can range from about 50° C. to about 200° C. In certain embodiments, the temperature can be about 100° C. The introduction of pressure can be from the bladder of the laminator. The pressure can range from about 1 psi to about 20 psi. A gradual increase of the temperature and/or pressure allows sufficient opportunity for the air in the module to be evacuated before sealing occurs. The entire photovoltaic module 10 can be laminated and sealed to preserve the module in a substantially air-free environment.

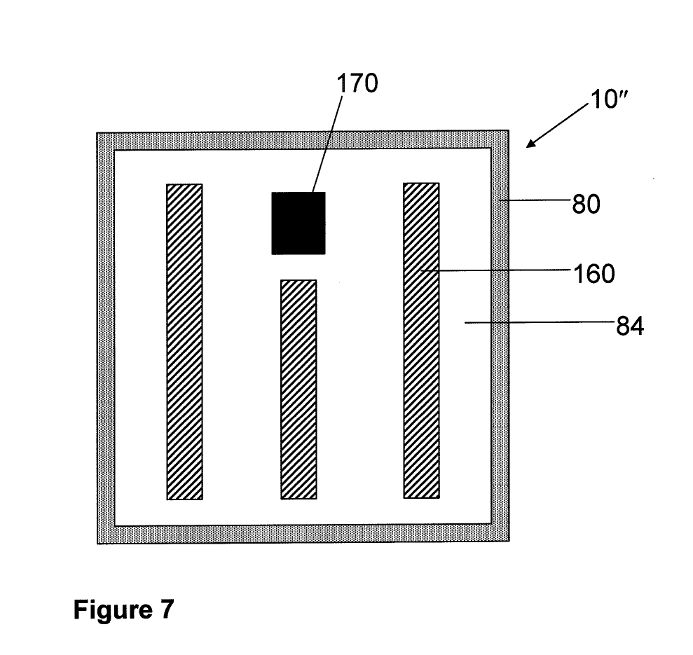

FIG. 7 shows the back surface 84 of the back sheet layer 50 of photovoltaic module 10″. The dimensions of the photovoltaic module 10″ are about 3′ wide and about 5′ high. Edge element 80 is disposed on the edge of the photovoltaic component 20. Elements 160 are bonded to the back surface 84 of the backsheet layer 50. The elements can be non-metallic. The elements 160 can act as stiffening members to increase the rigidity of the photovoltaic module 10″. The elements 160 can be vertical and located in a position to provide maximum stiffness to the photovoltaic module 10″.

The elements 160 can be used to attach the photovoltaic module 10″ to a mounting structure, such as, a rack or frame mounted on a roof surface. In certain embodiments, the elements 160, which can include bars or rods of a composite and/or non-metallic material including a polymer and/or a filler, can be positioned horizontally or diagonally on the backsheet layer 50 side of the photovoltaic module 10″. The photovoltaic module 10″ can include a junction box 170 attached to the back surface 84. The junction box 170 can be used to interconnect adjacent photovoltaic modules or can be used to connect photovoltaic module 10″ to a load.

Elements 160 can be placed on and bonded to the backsheet layer 50 to give the photovoltaic module 10″ a desired stiffness. The amount of stiffness necessary can increase as photovoltaic modules become larger. Larger modules traditionally require heavier and more costly aluminum frames. Even with this, there is a limit as to how much stiffness a frame that is only on the edges of the module can provide. Just as an aluminum frame is used both as a stiffening element and also as a means of mounting the module, non-metallic stiffening elements 160 placed on the back of the module can also serve as mounting elements. The non-metallic stiffening elements 160 can have sufficient strength to withstand loads on the front surface of the module and similar loads against the rear surface of the module.

The classes of non-metallic materials that could be used as stiffening elements and/or mounting elements 160 can include, but are not limited to, polymers that contain fillers to give them additional stiffness, mechanical strength, and/or flame retardant properties. Examples of traditional fillers include, but are not limited to, aluminum trihydrate, calcium carbonate, calcium sulfate, carbon fibers, glass fibers, hollow glass microspheres, kaolin clay, mica, crushed silica, synthetic silica, talc, and wollastonite. In some embodiments, nano-clays such as montmorillinite can be used as fillers. The nano-clays can provide enhanced physical and/or flame retardant properties for very small quantities that are added to the polymer.

For low-cost materials, the polymer material can be a polyolefin such as high density polyethylene and polypropylene. In certain embodiments, PET can be used. Some of the polyolefins and PET can be recycled materials instead of virgin resins and thereby even lower in cost.

In various embodiments, composites of sawdust from wood along with various polymers such as PVC and polyolefins such as plastic lumber can be used. These materials can also be blended with nanoparticles of clay to further enhance their physical properties.

### INCORPORATION BY REFERENCE

Suitable materials for photovoltaic modules and/or suitable techniques for forming one or more components of a photovoltaic module are described in one or more of the following U.S. patents, each owned by the assignee of the present application and the entire disclosure of each incorporated by reference: U.S. Pat. Nos. 5,741,370; 6,114,046; 6,187,448; 6,320,116; 6,353,042; and 6,586,271.

Variations, modifications, and other implementations of what is described herein will occur to those of ordinary skill in the art without departing from the spirit and the scope of the invention. Accordingly, the invention is not to be limited only to the preceding illustrative descriptions.

What is claimed is:

1. A method of forming a photovoltaic module, comprising:
extruding a polymer material to form at least one edge element;
irradiating the at least one edge element to cross-link the polymer material;
bonding the at least one edge element to a photovoltaic component including a plurality of interconnected photovoltaic cells disposed between a transparent layer and a backsheet layer, the at least one edge element bonded to a front surface of the transparent layer and a back surface of the backsheet layer; and
laminating the at least one edge element and the photovoltaic component, in the absence of a mold, to form the photovoltaic module.

2. The method of claim 1 wherein the at least one edge element comprises a single member disposed around the perimeter of the photovoltaic component.

3. The method of claim 1 wherein the at least one edge element comprises edge members and corner members.

4. The method of claim 3 further comprising overlapping the corner members over the edge members.

5. The method of claim 1 further comprising disposing a bonding agent on a surface of the at least one edge element prior to the bonding step.

6. The method of claim 1 further comprising irradiating the at least one edge element with an energy of about 2 MR to about 20 MR.

7. The method of claim 1 wherein the at least one edge element comprises a non-electrically conductive material.

8. The method of claim 1 further comprising irradiating the edge element to sufficiently cross-link the polymer material so that the polymer material does not flow during the lamination step.

9. The method of claim 5 further comprising irradiating the bonding agent.

10. A method of forming a laminated photovoltaic module, comprising:
providing a photovoltaic component including a plurality of electrically connected photovoltaic cells disposed between a backsheet layer and a transparent layer;
attaching at least one edge member comprising a first irradiated polymer on the photovoltaic component so as to contact a front surface of the transparent layer and a back surface of the backsheet layer;
attaching at least one corner member comprising a second irradiated polymer on the photovoltaic component so as to contact the front surface of the transparent layer and the back surface of the backsheet layer, and to form together with the at least one edge element at least a portion of a non-conductive frame about the photovoltaic component; and
laminating the photovoltaic component together with the at least one edge member and the at least one corner member to form the laminated photovoltaic module.

11. The method of claim 10 further comprising attaching at least four edge members to the photovoltaic component.

12. The method of claim 11 further comprising attaching four corner members to the photovoltaic component and the at least four edge members.

13. The method of claim 12 further comprising overlapping each corner member over two edge members.

14. The method of claim 10 further comprising disposing a bonding layer on a surface of each edge member prior to attaching the edge members to the photovoltaic component.

15. The method of claim 14 wherein the bonding layer comprises an acid co-polymer of methacrylic acid.

16. The method of claim 14 wherein the bonding layer comprises an acid co-polymer of acrylic acid and polyethylene.

17. The method of claim 14 wherein the bonding layer comprises an ionomer.

18. The method of claim 14 further comprising irradiating the at least one edge member and the bonding layer with an energy of about 2 MR to about 20 MR prior to attaching the at least one edge member to the photovoltaic component.

19. The method of claim 18 further comprising disposing the bonding layer on each corner member and irradiating the bonding layer and each corner member with an energy of about 2 MR to about 20 MR prior to attaching the corner members to the photovoltaic component.

20. The method of claim 18 further comprising applying a silane coupling agent to at least a portion of the transparent layer prior to attaching the at least one edge member to the photovoltaic component.

21. The method of claim 10 further comprising attaching at least one non-electrically conductive mounting element to the laminated photovoltaic module.

22. The method of claim 21 wherein the non-electrically conductive mounting element comprises a filled polymer.

23. The method of claim 22 wherein the filled polymer includes a filler selected from the group consisting of aluminum trihydrate, calcium carbonate, calcium sulfate, carbon fibers, glass fibers, hollow glass microspheres, kaolin clay, mica, crushed silica, synthetic silica, talc, wollastonite, nano-clay particles, and sawdust.

24. A system for protecting edges of a photovoltaic module, comprising:
a plurality of edge members comprising a first irradiated polymer and adapted to physically contact both an upper surface and a lower surface of the photovoltaic module, each edge member sealing a respective edge of the photovoltaic module; and
a plurality of corner members comprising a second irradiated polymer and adapted to physically contact both the upper surface and the lower surface of the photovoltaic module, each corner member sealing a respective corner of the photovoltaic module.

25. The system of claim 24 wherein the first irradiated polymer and the second irradiated polymer are formed from a same initial polymer material.

26. The system of claim 24 wherein the first irradiated polymer is irradiated at a dosage to create both thermoset and thermoplastic properties.

27. The system of claim 24 wherein the second irradiated polymer is irradiated at a dosage of about 2 MR to about 20 MR.

28. The system of claim 24 wherein each edge member is tapered.

29. The system of claim 24 wherein each edge member has a U-shape.

30. The system of claim 24 wherein each corner member has a hollow L-shape.

31. The system of claim 24 further comprising a bonding layer disposed on at least a portion of an interior surface of each edge member so as to contact at least one of the upper surface and the lower surface of the photovoltaic module.

32. The system of claim 31 wherein the bonding layer is irradiated with an electron beam.

33. The system of claim 24 further comprising a bonding layer disposed on at least a portion of an interior surface of each corner member so as to contact at least a portion of the respective corner of the photovoltaic module.

34. A photovoltaic module comprising:
a lower support layer;
an upper support layer comprising a transparent sheet;
a photovoltaic layer positioned between the lower support layer and the upper support layer, the photovoltaic layer comprising a plurality of electrically connected photovoltaic cells; and
a non-conductive frame comprising at least one irradiated polymer element adapted to contact a portion of the lower support layer and the upper support layer;
wherein the lower support layer, the upper support layer, the photovoltaic layer, and the non-conductive frame are laminated to form the photovoltaic module.

35. The photovoltaic module of claim 34 wherein each of the irradiated polymer elements overlap at least one other irradiated polymer element to form the non-conductive frame.

36. The photovoltaic module of claim 34 wherein the irradiated polymer elements include at least one edge member and at least one corner member.

37. The photovoltaic module of claim 34 wherein the irradiated polymer elements have both thermoset and thermoplastic properties.

38. The photovoltaic module of claim 34 further comprising at least one non-electrically conductive mounting element disposed on a lower support layer side of the photovoltaic module, the at least one non-electrically conductive mounting element providing an increase in stiffness to the photovoltaic module.

39. The photovoltaic module of claim 38 wherein the at least one non-electrically conductive mounting element is made of a composite material including a polymer and a filler.
